(19) United States
(12) Patent Application Publication
(10) Pub. No.: US 2021/0174986 A1
(43) Pub. Date: Jun. 10, 2021

(54) TRANSPARENT CONDUCTIVE FILM AND THE FABRICATION METHOD THEREOF

(71) Applicant: NANOTECH & BEYOND CO., LTD., Daejeon (KR)

(72) Inventors: Sang Ho KIM, Sejong-si (KR); Chang Woo SEO, Sejong-si (KR); Jin E LEE, Daejeon (KR)

(21) Appl. No.: 16/071,403

(22) PCT Filed: May 25, 2018
(86) PCT No.: PCT/KR2018/005969

§ 371 Date: Jul. 19, 2018

(30) Foreign Application Priority Data
May 29, 2017 (KR) 1-2017-0066418
May 29, 2017 (KR) 10-2017-0066414
May 23, 2018 (KR) 10-2018-0058430

(51) Int. Cl. H01B 5/14; H05K 1/09

(52) U.S. Cl. CPC H01B 5/14; B82Y 40/00; H05K 1/092

(57) ABSTRACT

The present invention relates to an ultra large area nanowire transparent electrode, including a transparent insulating substrate, and a metal nanowire network, wherein Rₘ denoting an average sheet resistance of a nanowire transparent electrode having a width of 10 cm and a length of 2 m is 55 Ω/sq., or less, and each sheet resistance in 500 divided regions defined by evenly dividing the entire region of the nanowire transparent electrode having a width of 10 cm and a length of 2 m into an area of 2 cm×2 cm satisfies 0.5Rₘ to 1.5Rₘ.

### TECHNICAL FIELD

The present invention relates to a nanowire transparent electrode and a manufacturing method thereof, and more particularly, to a nanowire transparent electrode based on a conductive nanowire and having excellent commercial properties, and a manufacturing method thereof.

### BACKGROUND ART

A nanowire transparent electrode means a thin conductive film coated on an insulating substrate having high light transmittance. The nanowire transparent electrode has appropriate optical transparency and has surface conductivity. The nanowire transparent conductor having surface conductivity is widely used as a transparent electrode in fields where both transparency and conductivity are simultaneously required, such as flat liquid crystal displays, touch panels, electroluminescent devices, and photovoltaic cells, etc., and is also widely used as anti-static layers or as electromagnetic wave shielding layers.

Metal oxides such as indium tin oxide (ITO) have excellent optical transparency and electrical conductivity, but have limitation in that high cost is required, and a high-temperature process is required at the time of preparation while having disadvantages in that they are easily damaged by physical impact and are not physically deformable.

A conductive polymer has problems in that not only electrical and optical properties are deteriorated but also chemical and long-term stability are deteriorated.

Accordingly, a demand for the nanowire transparent conductor capable of having excellent electrical and optical properties, stably maintaining physical properties thereof for a long period of time, and being physically deformable has been continuously increased.

In accordance with this demand, the transparent conductor having a structure in which a network of metal nanowires such as silver nanowires are embedded in an organic matrix on an insulating substrate, as described in Korean Patent Laid-Open Publication No. 2013-0135186, has been developed.

However, the metal nanowire-based nanowire transparent electrode has difficulty in commercialization since it is difficult to obtain a uniform electric property at the time of forming a large area, and a manufacturing process suitable for mass production using a continuous process is not established.

### DISCLOSURE

### Technical Problem

An object of the present invention is to provide a nanowire transparent electrode having uniform electrical and optical properties even in an ultra large area having a width of at least 10 cm or more and a length ranging from several to several tens of meters to thereby have excellent commercial properties.

Another object of the present invention is to provide a manufacturing method of a nanowire transparent electrode capable of rapidly manufacturing a nanowire transparent electrode having uniform and excellent electrical and optical properties in a very simple process, resulting in construction of a commercial manufacturing process.

### Technical Solution

In one general aspect, a nanowire transparent electrode includes: a transparent insulating substrate; and a metal nanowire network, wherein the nanowire transparent electrode satisfies Relational Expression 1 and Relational Expression 2 below:

Rₘ≤55 Ω/sq. (Relational Expression 1)

(in Relational Expression 1, Rₘ is an average sheet resistance of a nanowire transparent electrode having a width of 10 cm and a length of 2 m)

0.5Rₘ≤R_{loc}(i)≤1.5Rₘ (Relational Expression 2)

(in Relational Expression 2, Rₘ is an average sheet resistance of a nanowire transparent electrode having a width of 10 cm and a length of 2 m, R_{loc} denotes an average sheet resistance of a nanowire transparent electrode having a width of 10 cm and a length of 2 m, indicating a sheet resistance in one divided region out of 500 divided regions defined by evenly dividing the entire region of the nanowire transparent electrode having a width of 10 cm and a length of 2 m into an area of 2 cm×2 cm, and R_{loc}(i) denotes a sheet resistance of a divided region corresponding to i in sequentially numbered 500 divided regions, wherein i is a natural number of 1 to 500).

A refractive index of the transparent insulating substrate may be 1.45 to 2.00.

The nanowire transparent electrode may further satisfy Relational Expression 3 below:

(R₅₀₀₀₀₀−R₀)/R₀×100≤3.0(%) (Relational Expression 3)

in Relational Expression 3, R₀ is an average sheet resistance of the nanowire transparent electrode, and R₅₀₀₀₀₀ is an average sheet resistance after performing an in-folding test 500,000 times on the nanowire transparent electrode having a size of 5 cm×5 cm with a curvature radius of 1 mm.

The nanowire transparent electrode may have a light transmittance of 90% or more and a haze of 1.5% or less.

The metal nanowire network may be obtained by applying a wire dispersion including a metal nanowire, an organic binder, and a solvent dissolving the organic binder onto the transparent insulating substrate, then filtering a white light so as to remove light corresponding to a central wavelength of a first peak which is an absorption peak having the highest intensity relatively among absorption peaks of the following third spectrum, and irradiating the filtered light:

first spectrum: ultraviolet-visible light absorption spectrum of the transparent insulating substrate

second spectrum: ultraviolet-visible light absorption spectrum of a reference body in a state in which the wire dispersion including a metal nanowire, an organic binder, and a solvent dissolving the organic binder is applied onto the transparent insulating substrate, and then the solvent is volatilized and removed

third spectrum: spectrum obtained by removing the first spectrum from the second spectrum.

The nanowire transparent electrode may be obtained by applying the above-described wire dispersion and performing light sintering by irradiating the filtered light, and may further satisfy Relational Expressions 4 and 5 below:

0.95≤H_{TCF}/H_{REF}≤1.05 (Relational Expression 4)

(in Relational Expression 4, H_{TCF} is a haze (%) of the nanowire transparent electrode, and H_{REF} is a haze (%) of the reference body before the wire dispersion is applied onto the transparent insulating substrate and light sintering is performed).

0.95≤T_{TCF}/T_{REF}≤1.05 (Relational Expression 5)

(in Relational Expression 5, T_{T}C_{F} is a light transmittance (%) of the nanowire transparent electrode, and T_{REF} is a light transmittance (%) of the reference body before the wire dispersion is applied onto the transparent insulating substrate and light sintering is performed).

The metal nanowire network may include a crossing region where two or more metal nanowires cross each other, and a height of the crossing region may satisfy Relational Expression 6 below:

0.5≤hc/(d1+d2)≤0.7 (Relational Expression 6)

(in Relational Expression 6, d1 denotes a height of one metal nanowire of two or more metal nanowires forming the crossing region based on a surface of the transparent insulating substrate, d2 denotes a height of the other metal nanowire of two or more metal nanowires forming the same crossing region based on the surface of the transparent insulating substrate, and hc denotes a height of the crossing region based on the surface of the transparent insulating substrate).

The metal nanowire network may include a crossing region where two or more metal nanowires cross each other, and the metal nanowire disposed at an upper part in the crossing region may satisfy Relational Expression 7 below:

0.6do≤dnc≤1do (Relational Expression 7)

(in Relational Expression 7, do denotes, in a metal nanowire disposed at the upper part in the crossing region, a height of the metal nanowire based on a surface of the transparent insulating substrate at a point not in contact with the other metal nanowire by at least 100 nm or more in a length direction of the nanowire, and dnc denotes, in the same metal nanowire disposed at the upper part in the crossing region, a height of the metal nanowire based on the surface of the transparent insulating substrate in a region within 50 nm extending in the length direction of the metal nanowire at an edge of the crossing region).

In another general aspect, a manufacturing method of a nanowire transparent electrode includes, based on a first spectrum which is an ultraviolet-visible light absorption spectrum of a transparent insulating substrate, a second spectrum which is an ultraviolet-visible light absorption spectrum of a reference body in a state in which a wire dispersion including a metal nanowire that generates surface plasmon, an organic binder, and a solvent that dissolves the organic binder is applied onto the transparent insulating substrate, and then the solvent is volatilized and removed, and a third spectrum obtained by removing the first spectrum from the second spectrum, applying the wire dispersion onto the transparent insulating substrate, then filtering a white light so as to remove light corresponding to a central wavelength of a first peak which is an absorption peak having the highest intensity relatively among absorption peaks of the third spectrum, and irradiating the filtered light, thereby performing light sintering.

The filtering may be performed so as to pass light corresponding to a central wavelength of a second peak which is an absorption peak having a second highest intensity relatively among the light absorption peaks of the third spectrum.

The filtering may be performed so as to remove light having a wavelength more than 1.3 times the central wavelength of the second peak at the time of the filtering.

The filtering may be band-pass filtering, and a minimum wavelength of the filtered light may be disposed between the center wavelength of the first peak and the center wavelength of the second peak.

A bandwidth which is a difference between a maximum wavelength and the minimum wavelength of the filtered light may be 150 nm or less.

A pass band of the band-pass filter based on the wavelength may have the minimum wavelength of 380 to 410 nm and the maximum wavelength of 430 to 550 nm.

At the time of the light sintering using the filtered light, the filtered light irradiated onto the transparent insulating substrate in which the wire dispersion is applied may have a fluence of 6 to 10 J/cm².

The applying of the wire dispersion and the light sintering may be continuous processes.

The manufacturing method may include unwinding the transparent insulating substrate wound in a roll form; applying the wire dispersion to the unwound transparent insulating substrate; light sintering of irradiating the filtered light onto the transparent insulating substrate onto which the wire dispersion is applied; and washing the light-irradiated transparent insulating substrate and rewinding the transparent insulating substrate again in a roll form.

In still another general aspect, there is provided a nanowire transparent electrode manufactured by the manufacturing method as described above.

### Advantageous Effects

The nanowire transparent electrode according to the present invention has excellent light transmittance, low haze, remarkably low sheet resistance, and very uniform sheet resistance in an ultra large entire region despite having an ultra large area having a width of 10 cm or more and a length of several meters, thereby very good commerciality. Further, the nanowire transparent electrode according to the present invention has a sheet resistance reduction rate of 3.0% or less, specifically 2.0% or less, more specifically 1.5% or less, even at a repetition test of 500,000 times under ultimate in-folding test conditions of 1 mm, and thus reduction in electrical properties is remarkably suppressed even with repetitive deformation.

According to the manufacturing method of the nanowire transparent electrode of the present invention, it is possible to manufacture the nanowire transparent electrode according to the present invention can manufacture a nanowire transparent electrode having significantly excellent electrical and optical properties and uniform properties even in a very large area through a very simple process such as coating of a wire dispersion liquid and irradiation of filtered light, thereby making it possible to mass-produce a high-quality nanowire transparent electrode through continuous processes such as roll-to-roll, and the like, and thus there is an advantage of having very good commerciability.

### DESCRIPTION OF DRAWINGS

FIG. 1 is an optical image of a process of manufacturing a nanowire transparent electrode by a roll-to-roll process according to an embodiment of the present invention.

FIG. 2 shows a first spectrum which is an ultraviolet-visible light absorption spectrum of a transparent insulating substrate according to an embodiment of the present invention.

FIG. 3 shows a second spectrum which is an ultraviolet-visible light absorption spectrum of a transparent insulating substrate to which a wire dispersion liquid is applied according to an embodiment of the present invention.

FIG. 4 shows a third spectrum obtained by removing the first spectrum from the second spectrum, according to an embodiment of the present invention.

FIG. 5 is a scanning electron microscope (SEM) image of the manufactured nanowire transparent electrode.

FIG. 6 is an optical image showing an in-folding test of the manufactured nanowire transparent electrode.

### BEST MODE

Hereinafter, a nanowire transparent electrode according to the present invention and a manufacturing method thereof are described in detail with reference to the accompanying drawings. The drawings to be described below are provided by way of example so that the idea of the present invention can be sufficiently transferred to those skilled in the art to which the present invention pertains. Therefore, the present invention may be implemented in many different forms, without being limited to the drawings to be described below. The drawings may be exaggerated in order to specify the spirit of the present invention. Meanwhile, unless technical and scientific terms used herein are defined otherwise, they have meanings understood by those skilled in the art to which the present invention pertains. Known functions and components will be omitted so as not to obscure the description of the present invention with unnecessary detail.

The present applicant noted that in order to commercialize a metal nanowire-based nanowire transparent electrode, large-scale production by large-scale with quick and simple continuous processes were required to be essentially performed, and conducted the research continuously.

As a result, the present applicant found that in order to ensure uniformity of the application of the metal nanowires, it was required to use a dispersion of metal nanowires containing an organic binder, and when white light was irradiated on the transparent insulating substrate to which the metal nanowires were applied, light of a wavelength band corresponding to an absorption peak having the strongest intensity among the light absorption peaks in the metal nanowire absorption spectrum in a state in which the metal nanowires were applied onto the transparent insulating substrate had a rather adverse effect on light sintering.

Based on this finding, as a result of intensifying the research, it was found that, in the ultraviolet-visible (UV-Vis) absorption spectrum of the metal nanowire in the state of being applied onto the transparent insulating substrate, when irradiating light by filtering the white light so that light having a wavelength corresponding to one specific peak was removed, and light having a wavelength corresponding to the other one specific peak was passed, it was possible to manufacture the nanowire transparent electrode having significantly lower sheet resistance even with a significantly low fluence, without damaging the nanowire or transparent insulating substrate, and further, it was possible to manufacture a nanowire transparent electrode having very uniform properties having substantially almost the same sheet resistance even in an ultra large area.

In addition, it was found that when the white light was filtered so that the light corresponding to one specific peak was removed, and light corresponding to the other one specific peak was passed, and at the same time the light sintering was performed by removing light of a long wavelength close to a heat line and concentrating all the energy of the light to be irradiated in a wavelength band corresponding to one specific peak, an organic binder disposed at the contact point of the nanowire was decomposed and the light sintering was very effectively performed. In other words, when the unfiltered white light was irradiated and the fluence of light increased, the nanowire or the transparent substrate was damaged before decomposition of the organic binder, and thus a process of decomposing the organic binder such as ultraviolet ray was required. However, the present applicant found that when all the light energy was concentrated in the wavelength band of the light corresponding to the specific peak on the ultraviolet-visible (UV-Vis) absorption spectrum of the metal nanowire in the state of being applied onto the transparent insulating substrate using a band-pass filter, the organic binder was decomposed even at a remarkably low optical fluence and the decomposition of the organic binder and the light sintering were simultaneously performed by a single light irradiation (irradiation of the filtered light), and filed the present invention.

As known in the art, the ultraviolet-visible light absorption spectrum means absorbance per wavelength of ultraviolet-visible light, wherein a wavelength of the light to be irradiated is plotted on an x-axis, and absorbance, which is a log value of a ratio (I₀/I₁) of an irradiated radiation amount (I₀) to a transmitted radiation amount (I₁), is plotted on a y-axis.

In the present invention, a first spectrum is an ultraviolet-visible light absorption spectrum of the transparent insulating substrate itself used for manufacturing the nanowire transparent electrode, and a second spectrum is an ultraviolet-visible light absorption spectrum of a reference body obtained by applying a wire dispersion including a metal nanowire, an organic binder, and a solvent dissolving the organic binder onto the same substrate as the transparent insulating substrate used for the first spectrum measurement, and then volatilizing and removing the solvent. A third spectrum is a spectrum calculated by removing the first spectrum from the second spectrum, wherein a difference in absorbance obtained by subtracting an absorbance value at the same wavelength of the first spectrum from an absorbance value per wavelength of the second spectrum is plotted on a y-axis. That is, when assuming that the first spectrum is represented as a function of y₁=f₁(x) (x=wavelength of ultraviolet-visible light, y₁=absorbance) and the second spectrum is represented as a function of y₂=f₂(x) (x=wavelength of ultraviolet-visible light, y₂=absorbance), the third spectrum may be represented by y₃=y₂−y₂=f₂(x)−f₁(x) (x=wavelength of ultraviolet-visible light, y₃=absorbance difference between first and second spectrums per wavelength). Here, the first spectrum or the second spectrum may be subjected to data process such as scattering, noise correction, smoothing, or the like through a conventional program used at the time of measuring ultraviolet-visible light absorption spectrum according to the related art.

Further, when the absorbance according to the wavelength continuously increases in the one absorption spectrum (the first spectrum, the second spectrum or the third spectrum), reached to the apex, and then decreases continuously (on the primary differential spectrum of the absorption spectrum, the value is continuously changed from a positive value to a negative value through 0), it may be recognized as one absorption peak. The wavelength at the center of the absorption peak may mean a wavelength corresponding to the apex of the peak, that is, a wavelength at a zero (0) point when the positive value is changed to the negative value on the primary differential spectrum of the absorption spectrum, and a wavelength at the center of the absorption peak is referred to as the center wavelength or the peak wavelength, and the absorption value at the center of the absorption peak is referred to as the peak intensity or intensity.

As described above, a manufacturing method of a nanowire transparent electrode includes, based on a first spectrum which is an ultraviolet-visible light absorption spectrum of a transparent insulating substrate, a second spectrum which is an ultraviolet-visible light absorption spectrum of a reference body in a state in which a wire dispersion including a metal nanowire that generates surface plasmon, an organic binder, and a solvent that dissolves the organic binder is applied onto the transparent insulating substrate, and the solvent is volatilized and removed, and a third spectrum obtained by removing the first spectrum from the second spectrum, applying the wire dispersion onto the transparent insulating substrate, then filtering a white light so as to remove light corresponding to a central wavelength (hereinafter, λ_{fpeak}) of a first peak which is an absorption peak having the highest intensity (peak intensity) relatively among absorption peaks of the third spectrum, and irradiating the filtered light, thereby performing light sintering.

Here, the first spectrum and the second spectrum may be spectrums measured in a state in which only the object to be measured is changed in a state where all conditions that may affect the absorption spectrum are identical to each other. As the first spectrum is removed from the second spectrum to obtain the third spectrum, the third spectrum may correspond to the absorption spectrum of the metal nanowires themselves in a state in which the metal nanowires are applied onto the transparent insulating film and light sintering is not performed.

It is advantageous that at the time of filtering the white light, the filtering is performed so as to pass light corresponding to the center wavelength of the second peak which is the absorption peak having a second highest intensity (peak intensity) relatively among the light absorption peaks of the third spectrum.

More specifically, at the time of the filtering, the filtering of the white light may be performed so as to remove the light corresponding to the center wavelength of the absorption peak having the highest intensity (peak intensity) relatively in the wavelength range of 300 to 600 nm in the third spectrum, and at the same time, to pass light corresponding to the center wavelength of the absorption peak having a second highest intensity (peak intensity) relatively in the wavelength range of 300 to 600 nm.

By the filtering in which the light corresponding to the center wavelength (hereinafter, λ_{fpeak}) of the first peak is removed and the light corresponding to the center wavelength (hereinafter, λₛₚₑₐₖ) of the second peak is passed, contact (crossing) points between the metal nanowires may be subjected to stable melting bonding as they are in the applied state without damaging or deforming the metal nanowire and the transparent insulating substrate, and all the contact (crossing) points may be uniformly and evenly melting bonded even in a large area.

Previous experiments on silver nanowires having various sizes and various types of transparent insulating substrates have shown that the first and second peaks in the third spectrum are disposed in the wavelength range of 300 to 600 nm, specifically 350 to 450 nm, and in all cases, the center wavelength of the first peak was shorter than the center wavelength of the second peak.

Upon considering that in the ultraviolet-visible absorption spectrum of the silver nanowires dispersed in a simple liquid phase, a single absorption peak is formed, and that as the silver nanowires are applied to the transparent insulating substrate, even though the absorption by the substrate is removed, at least two or more absorption peaks including the first and second peaks are formed, the first peak and the second peak may be interpreted as being caused by the contact between the silver nanowire and the insulating transparent substrate and the contact between the silver nanowires. In this aspect, although not limited to this interpretation, the first and second peaks in the third spectrum may be interpreted as peaks caused by other plasmon resonance such as local surface plasmon resonance (LSPR) and propagating surface plasmon resonance (PSPR) occurring at the contact point between the metal nanowires, and the local surface plasmon resonance, which occurs at a hot spot which is the contact point between metal nanowires, has air as a medium, and since a refractive index of the medium other than air in contact with silver nanowires, such as a transparent insulating substrate, is larger than that of the air, it is possible to predict that plasmon resonance wavelengths other than the local surface plasmon resonance (LSPR) such as propagating surface plasmon resonance (PSPR) is able to be blue-shifted based on the LSPR wavelength.

Therefore, the second peak may be interpreted as light absorption by the local surface plasmon resonance absorbed at the contact point between the nanowires (the contact point between the nanowires with at least air interposed therebetween), and the first peak is the propagating surface plasmon resonance (PSPR), and the first peak may be interpreted as light absorption by plasmon resonance other than the local surface plasmon resonance (LSPR). That is, the light absorption (second peak) by the local surface plasmon resonance (LSPR) plays a role by light sintering (melting bonding) the contact points between the nanowires, but another type of plasmon resonance, such as the propagating surface plasmon resonance (PSPR), caused by the interaction between the metal nanowire and the medium other than air, rather acts as an inhibitor of uniform light bonding, and thus it is advantageous to remove this type of plasmon resonance.

As described above, the center wavelength of the first peak may be shorter than the center wavelength of the second peak. Advantageously, stable light sintering may be achieved by low fluence, a separate light irradiation (light irradiation except for the filtered light) such as ultraviolet irradiation may be excluded, and filtering may be performed so as to remove light having a wavelength more than 1.3 times the center wavelength (λₛₚₑₐₖ) of the second peak at the time of the filtering in order to prevent damage to the substrate.

The filtering of the white light so that the center wavelength of the first peak is removed and simultaneously the light having a wavelength more than 1.3 times the center wavelength (λₛₚₑₐₖ) of the second peak is removed at the time of the filtering, although not limited to this interpretation, may mean that when the light is irradiated, generation of plasmon resonance other than local surface plasmon resonance is basically blocked, and that all the energy of the light to be irradiated is concentrated in a local surface plasmon resonance wavelength band of a contact point between metal nanowires in an exposed state in the air, thereby performing light sintering.

Previous experiments have shown that when unfiltered white light is irradiated, a nanowire or a transparent substrate is damaged before decomposition of an organic binder as light fluence increases, and thus it was required to perform a process of removing the organic binder by ultraviolet irradiation in advance. However, it has shown that when all the light energy is concentrated in the local surface plasmon resonance wavelength band by filtering the light, the organic binder disposed in a contact region between nanowires is decomposed even in the remarkably low light fluence, and the decomposition of the organic binder and the light sintering are simultaneously generated by single light irradiation (irradiation of band-pass filtered light).

Further, by the filtering in which the light corresponding to the center wavelength (λ_{fpeak}) of the first peak is removed, the light corresponding to the center wavelength (λ_{fpeak}) of the second peak is passed, and the light having a wavelength more than 1.3 times the central wavelength (λ_{fpeak}) of the second peak is removed, melting bonding may be stably generated at contact points having various types between metal nanowires and contact points between metal nanowires having a predetermined size distribution (size distribution of short axis diameter).

More advantageously and substantially, the filtering of the white light may be a band-pass filtering, and a minimum wavelength (λ_{fmin}) of the filtered light may be disposed between the center wavelength (λ_{fpeak}) of the first peak and the center wavelength (λₛₚₑₐₖ) of the second peak.

When expressing this relationship as an expression, λ_{fpeak}<λ_{fmin}<λₛₚₑₐₖ may be satisfied, and when the maximum wavelength of the band-pass filtered light is represented by λ_{fmax}, λₛₚₑₐₖ<λ_{fmax}≤1.3λₛₚₑₐₖ may be satisfied. Here, as the frequency and the wavelength have a reciprocal relationship, λ_{fmax} may correspond to a low pass cutoff frequency (f_{L}) of the band-pass filter used for filtering the white light, λ_{fmin} may correspond to a high pass cutoff frequency (f_{H}) of the band-pass filter, and the wavelength band of the filtered light, i.e., the wavelength band of λ_{fmin} to λ_{fmax} may correspond to a bandwidth (B) of the band-pass filter.

As a substantial example, the bandwidth that is the difference between the minimum wavelength (λ_{fmin}) and the maximum wavelength (λ_{fmax}) of the band-pass filtered light may be 150 nm or less, preferably 100 nm or less, and substantially 50 nm to 100 nm.

As a practical example, the minimum wavelength (λ_{fmin}) of the band-pass filtered light may be 380 to 410 nm and the maximum wavelength (λ_{fmax}) may be 430 nm to 550 nm, and as a more practical example, the minimum wavelength (λ_{fmin}) may be 390 to 410 nm, and the maximum wavelength (λ_{fmax}) may be 430 to 520 nm.

In the manufacturing method of a nanowire transparent electrode according to an embodiment of the present invention, even if the fluence of the irradiated light (filtered light) is remarkably low, stable light sintering may be generated by selecting and irradiating a light in a band that acts to bond the metal nanowire at the crossing region (contact point) between the metal nanowires by the band-pass filtering based on the third spectrum.

As a specific example, at the time of light sintering using the filtered light, the fluence of the filtered light irradiated on the transparent insulating substrate onto which the wire dispersion is applied may be 6 to 10 J/cm². The filtered light and the low fluence may significantly reduce adverse effects (distortion or deformation of metal nanowires, reduction of partial short axis diameter, substrate damage, etc.) on the metal nanowire and the transparent insulating substrate at the time of light sintering. In addition, at the time of light sintering using the filtered light, light irradiation may be performed with a single pulse. That is, only one (1) light pulse may be irradiated for light sintering. This is a possible condition obtained by achieving light sintering with very low fluence. Light may be irradiated with a single pulse having a width of substantially 5 to 20 msec, more substantially 5 to 15 msec. However, the light sintering by this single pulse irradiation may be implemented by the technical superiority of the present invention which is the light sintering by the filtered light and the low fluence, and the present invention may not be limited to the light irradiation with a single pulse. If necessary, it is possible to irradiate light with multiple pulses so as to satisfy the above-described fluences (total irradiated fluences), and the pulse width and inter-pulse interval at the time of irradiation with multiple pulses may be several tens to several hundreds of microseconds (μsec).

Specifically, on the basis of the third spectrum, as light in a band that acts to bond the metal nanowire by the band-pass filtering is selected and irradiated, and simultaneously light is irradiated with a remarkably low fluence, the arrangement and shape of the metal nanowires in a state of being applied onto the substrate may be maintained substantially the same as before the light irradiation, and melting bonding may be achieved at the contact points between the metal nanowires.

In the manufacturing method according to the embodiment of the present invention, the applying of the wire dispersion and the light sintering may be continuous processes. In other words, it may be a continuous manufacturing method in which the applying of the wire dispersion and the light sintering are continuously performed, respectively. The continuous manufacturing method is essential for the mass production of the nanowire transparent electrode, but has difficulty in continuous manufacturing since uniformity of electrical and optical properties, in particular, electrical properties is not guaranteed in the related art.

However, since it is not required to perform a separate light irradiation such as ultraviolet light, and the light sintering is performed by irradiating the filtered (band-pass filtered) white light as described above in a sheet form, and thus the manufacturing method according to an embodiment of the present invention may be excessively fast and simple, may be suitable for continuous process based on large area process, and may be used to manufacture the nanowire transparent electrode having excessively uniform electrical and optical properties even in a large area. However, the present invention may not be limited to the continuous process, and a batch process consisting of a discontinuous process is not excluded.

The applying of the wire dispersion may include printing, and specifically may be performed by any method known to be used for applying a dispersion containing a one-dimensional nanostructure such as carbon nanotubes or nanowires, such as inkjet printing, fine contact printing, imprinting, gravure printing, gravure-offset printing, flexographic printing, offset/reverse offset printing, slot die coating, bar coating, blade coating, spray coating, dip coating, and roll coating, and the like. However, in the continuous process, it is preferable to use more favorable application method for continuous application such as gravure printing, gravure-offset printing, flexographic printing, offset/reverse offset printing, slot die coating, and bar coating, and the like.

After the above-described application is performed, a drying step for volatilizing and removing the solvent in the wire dispersion (a dispersion medium of the metal nanowire and solvent that dissolves the organic binder) may be further performed. However, when the time interval of the light irradiation step for printing and light sintering is sufficient time for being volatilized and removed, a separate drying step need not be performed.

In other words, the drying step may be selectively performed according to the process design, and the drying may be performed by using room temperature volatilization drying, hot air or cold air drying, heat drying (thermal energy, infrared energy, or the like), or a combination thereof. The drying may be performed at a temperature (for example, 40 to 80° C.) at which the solvent is able to volatilized and removed without adversely affecting the substrate at the time of hot air or heating and drying. Further, after the sintering step by the light irradiation of the band-pass filtered white light is performed, a washing step using water or the like may be further performed, if necessary, similarly to the drying step.

The manufacturing method according to an embodiment of the present invention may be a roll-to-roll continuous process. In other words, the manufacturing method may include unwinding the transparent insulating substrate wound in a roll form; applying the wire dispersion to the unwound transparent insulating substrate; light sintering of irradiating the filtered light onto the transparent insulating substrate onto which the wire dispersion is applied; and washing the light-irradiated transparent insulating substrate and rewinding the transparent insulating substrate again in a roll form. As the light sintering may be single pulse irradiation of the band-pass filtered light, a process rate of the roll-to-roll continuous process (i.e., a rate at which the unwinding, the applying, and the light sintering are performed, and the transparent insulating substrate is rewound) may be 10 mm/sec, specifically, 30 mm/sec, and more specifically 50 mm/sec or more.

In the above-described manufacturing method and the nanowire transparent electrode to be described below, the metal nanowire may mean a nanowire of a metal in which surface plasmon is generated. As a specific example, the conductive nanowire having surface plasmon may be a nanowire of a material selected from one or more of gold, silver, lithium, aluminum, an alloy thereof, and the like, but the present invention is not limited thereto. An aspect ratio and a short axis diameter (average) of the metal nanowire may be any aspect ratio and any short axis diameter as long as it is advantageous in forming a conductive network providing a stable current moving path by contacting the nanowires to each other while minimizing reduction of transparency (light transmittance). As a substantial example, the metal nanowire may have an aspect ratio of 50 to 20000, and a short axis average diameter of 5 to 100 nm, but the present invention is not limited thereto.

The white light which is a subject to be filtered may be a Xenon lamp light, but is not limited thereto, and may be any light source known as a light source of a conventional white light similar to the Xenon lamp. The xenon flash lamp has a constitution including a xenon gas injected into a cylinder-shaped sealed quartz tube. This xenon gas outputs light energy from the input electrical energy, and has an energy conversion rate of more than 50%. In addition, a metal electrode such as tungsten is formed on both inner sides of the xenon lamp so as to form a positive electrode and a negative electrode. When a high power and current generated from a power source unit is applied to a lamp having the constitution, the injected xenon gas is ionized and a spark is generated between the positive electrode and the negative electrode. Here, an arc plasma shape is generated in the lamp through the spark generated in the lamp, and strong intensity light is generated. Here, since the generated light has a light spectrum having a wide wavelength band ranging from ultraviolet rays to infrared rays between 160 nm to 2.5 mm, the xenon lamp is well known as a kind of white light source.

The organic binder contained in the wire dispersion may be a low molecular natural polymer or a low molecular synthetic polymer having a molecular weight (weight average molecular weight) of 5×10⁵ or less, specifically 2×10⁵ or less. Here, as a substantial example, the organic binder may have a molecular weight of 3,000 or more, but the present invention is not limited by the lower limit of the molecular weight of the organic binder.

Substantially, the organic binder may be one or two or more selected from polyethylene glycol (PEG), polyvinylpyrrolidone (PVP), polyvinyl alcohol (PVA), polysaccharide, and a polysaccharide derivative.

More substantially, the organic binder may be one or two or more selected from a low molecular weight polyethylene glycol (PEG) having a molecular weight of 3,000 to 50,000, preferably 3,000 to 20,000, a low molecular weight polyvinylpyrrolidone (PVP) having a molecular weight of 3,000 to 60,000, a low molecular weight polyvinylalcohol (PVA) having a molecular weight of 3,000 to 50,000, a low molecular weight polysaccharide having a molecular weight of 3,000 to 200,000, preferably 3,000 to 100,000, and a low molecular weight polysaccharide derivative having a molecular weight of 3,000 to 200,000, preferably 3,000 to 100,000.

The low molecular weight polysaccharide may include glycogen, amylose, amylopectin, callose, agar, algin, alginate, pectin, carrageenan, cellulose, chitin, chitosan, curdlan, dextran, fructane, collagen, gellan gum, gum arabic, starch, xanthan, gum tragacanth, carayan, carabean, glucomannan, or a combination thereof. The polysaccharide derivative may include cellulose ester or cellulose ether.

The organic binder may be a low molecular weight cellulose ether and the cellulose ether may include carboxy-C1-C3-alkyl cellulose, carboxy-C1-C3-alkylhydroxy-C1-C3-alkyl cellulose, C1-C3-alkyl cellulose, C3-alkylhydroxy-C1-C3-alkyl cellulose, hydroxy-C1-C3-alkyl cellulose, mixed hydroxy-C1-C3-alkyl cellulose or a mixture thereof.

As an example, the carboxy-C1-C3-alkyl cellulose may include carboxymethyl cellulose, and the like, the carboxy-C1-C3-alkylhydroxy-C1-C3-alkyl cellulose may include carboxymethyl hydroxyethyl cellulose, and the like, the C1-C3-alkyl cellulose may include methyl cellulose, and the like, the C1-C3-alkylhydroxy-C1-C3-alkyl cellulose may include hydroxyethyl methyl cellulose, hydroxypropyl methyl cellulose, ethyl hydroxyethyl cellulose, or a combination thereof, and the like, the hydroxy-C1-C3-alkyl cellulose may include hydroxylethyl cellulose, hydroxypropyl cellulose or a combination thereof, and the like, and the mixed hydroxy-C1-C3-alkyl cellulose may include hydroxyethyl hydroxypropyl cellulose, or alkoxy hydroxyl ethylhydroxypropyl cellulose (the alkoxy group is a linear or branched chain and contains 2 to 8 carbon atoms), and the like.

The wire dispersion may contain 0.1 to 5 wt %, preferably 0.1 to 1 wt %, more preferably 0.1 to 0.7 wt %, of the organic binder. This content of the organic binder is a content capable of minimizing the organic binder present between the metal nanowires while uniformly and homogenously applying and fixing the wire dispersion on the substrate when the wire dispersion is applied.

The content of the metal nanowires in the wire dispersion may be appropriately adjusted according to the intended usage. Specifically, 0.01 to 70 parts by weight, more specifically 0.01 to 10 parts by weight, still more specifically 0.05 to 5 parts by weight, and still more specifically 0.05 to 0.5 part by weight of metal nanowires based on 100 parts by weight of solvent may be contained, but the content of the metal nanowires is not limited thereto, and may be appropriately controlled in consideration of the application method and the usage.

The solvent contained in the wire dispersion may be any solvent as long as it is a solvent capable of dissolving the organic binder, acting as a dispersion medium for the metal nanowires, and being easily volatilized and removed. As a specific example, the solvent may be 2-butoxyethyl acetate, propylene glycol monomethyl ether acetate, diethylene glycol monoethyl ether acetate, ethylene glycol butylether, cyclohexanone, cyclohexanol, 2-ethoxyethyl acetate, ethylene glycol diacetate, terpineol, isobutyl alcohol, water, or a mixed solution thereof, and the like. The present invention is not limited by the kind of the solvent contained in the wire dispersion.

In the transparent insulating substrate or when the transparent insulating substrate is a laminated substrate including a transparent insulating base film and a transparent insulating coating layer, the substrate may be rigid or flexible in view of physical properties. An example of the rigid transparent insulating substrate or the transparent insulating base film may include glass, polycarbonate, acrylic polyethylene terephthalate or the like, and an example of the flexible transparent insulating substrate, the transparent insulating base film or the transparent insulating coating layer may include polyesters such as polyester naphthalate and polycarbonate; polyolefins such as linear, branched, and cyclic polyolefins; polyvinyls such as polyvinyl chloride, polyvinylidene chloride, polyvinyl acetal, polystyrene and polyacryl; cellulose ester base-based such as cellulose triacetate or cellulose acetate; polysulfones such as polyethersulfone; polyimides or silicones, or the like, but the present invention is not limited thereto. However, a surface of the transparent insulating substrate (the coating layer or the transparent insulating substrate itself) in contact with the metal nanowire may have a refractive index of 1.45 to 2.00. This refractive index may allow the first and second peaks to be spaced apart, and thus at the time of band-pass filtering of white light, the light wavelength band belonging to the first peak and the wavelength band belonging to the second peak may be stably separated and filtered.

The present invention includes a nanowire transparent electrode manufactured by the manufacturing method as described above.

Hereinafter, the nanowire transparent electrode according to the present invention is described. In describing the nanowire transparent electrode, a metal nanowire, a transparent insulating substrate, a manufacturing method thereof, and the like, are similar to or the same as those described above in the manufacturing method of a nanowire transparent electrode.

The nanowire transparent electrode according to the present invention includes a transparent insulating substrate; and a metal nanowire network, and satisfies Relational Expressions 1 and 2 below:

Rₘ≤55 Ω/sq. (Relational Expression 1)

in Relational Expression 1, Rₘ is an average sheet resistance of a nanowire transparent electrode having a width of 10 cm and a length of 2 m. Specifically, Relational Expression 1 may be an average sheet resistance obtained by evenly dividing the entire region of the nanowire transparent electrode having a width of 10 cm and a length of 2 m into an area of 2 cm×2 cm, thereby forming 500 divided regions, and averaging sheet resistance in each divided region.

0.5Rₘ≤R_{loc}(i)≤1.5Rₘ (Relational Expression 2)

in Relational Expression 2, Rₘ is an average sheet resistance of a nanowire transparent electrode having a width of 10 cm and a length of 2 m, R_{loc} denotes a surface resistance in one divided region out of 500 divided regions defined by evenly dividing the entire region of the nanowire transparent electrode having a width of 10 cm and a length of 2 m into an area of 2 cm×2 cm, and R_{loc}(i) denotes a sheet resistance of a divided region corresponding to i in sequentially numbered 500 divided regions, wherein i is a natural number of 1 to 500.

As shown in Relational Expression 1, the nanowire transparent electrode according to the present invention may have very good electrical properties (low sheet resistance) with Rₘ of 55 Ω/sq or less, characteristically Rₘ of 50 Ω/sq or less, and more characteristically Rₘ of 45 Ω/sq or less, and further more characteristically Rₘ of 40 Ω/sq or less. In addition, in the ultra large area having a width of 10 cm and a length of 2 m, the nanowire transparent electrode may have very uniform electrical properties in which the sheet resistance measured in all the divided regions satisfies a value between 0.5Rₘ to 1.5Rₘ, characteristically, 0.6Rₘ to 1.4Rₘ, more characteristically, 0.7Rₘ to 1.3R^{m}, and still more characteristically, 0.8Rₘ to 1.2Rₘ, and further more characteristically, 0.85Rₘ to 1.15Rₘ, and still further more characteristically 0.95Rₘ to 1.05Rₘ. In the metal nanowire-based nanowire transparent electrode, the low sheet resistance as in Relational Expression 1 and the uniformity of very good electrical properties such as in Relational Expression 2 in this ultra large area have not been reported earlier.

As described above in the manufacturing method of the nanowire transparent electrode, when the transparent insulating substrate is a single layer, the refractive index of the transparent insulating substrate may be 1.45 to 2.00, and when the transparent insulating substrate includes a transparent insulating base film and a transparent insulating coating layer coated on the base film, the refractive index of the transparent insulating coating layer may be 1.45 to 2.00.

The nanowire transparent electrode according to an embodiment of the present invention may further satisfy Relational Expression 3 below:

(R₅₀₀₀₀₀−R₀)/R₀×100≤3.0(%) (Relational Expression 3)

in Relational Expression 3, R₀ is an average sheet resistance of the nanowire transparent electrode, and R₅₀₀₀₀₀ is an average sheet resistance after performing an in-folding test 500,000 times on the nanowire transparent electrode having a size of 5 cm×5 cm with a curvature radius of 1 mm.

The characteristic satisfying the Relational Expression 3 means that the contact points of the metal nanowires in the nanowire transparent electrode are melting bonded to each other to be stably integrated with each other, and the metal nanowires constituting the metal nanowire network forming a continuous current moving path in a direction of traversing the nanowire transparent electrode in the fusion process are substantially undamaged at all. That is, it is a physical property obtained when during the light sintering performed so that the metal nanowires forming the metal nanowire network are subjected to melting bonding at the contact points of the metal nanowires, the metal nanowires are not twisted or warped, or the short axis diameter is not partially changed, and stable melting bonding is achieved at the contact points of the metal nanowire while maintaining electrical and physical properties of the as-fabricated metal nanowire.

In detail, a sheet resistance change ratio ((R₅₀₀₀₀₀−R₀)/R₀×100) defined by the Relational Expression 3 of the nanowire transparent electrode according to an embodiment of the present invention may be 3.0% or less, more characteristically 2.0% or less, and further more characteristically 1.5% or less.

The nanowire transparent electrode according to an embodiment of the present invention may have a light transmittance of 90% or more and a haze of 1.5% or less, more specifically, a light transmittance of 90% or more and a haze of 1.35% or less. The light transmittance and haze may also be an average light transmittance or an average haze obtained by evenly dividing the entire region of the nanowire transparent electrode having a width of 10 cm and a length of 2 m into an area of 2 cm×2 cm, thereby forming 500 divided regions, and averaging light transmittance and haze in each divided region. Further, the light transmittance and the haze may be the light transmittance and haze that are all satisfied in each of the 500 divided regions where the entire region of the nanowire transparent electrode having a width of 10 cm and a length of 2 m is evenly divided into an area of 2 cm×2 cm.

In the nanowire transparent electrode according to an embodiment of the present invention, the metal nanowire network may be obtained by applying a wire dispersion including a metal nanowire, an organic binder, and a solvent dissolving the organic binder onto the transparent insulating substrate, then filtering a white light so as to remove light corresponding to a central wavelength of a first peak which is an absorption peak having the highest intensity relatively among absorption peaks of the following third spectrum, and irradiating the filtered light:

first spectrum: ultraviolet-visible light absorption spectrum of the transparent insulating substrate;

second spectrum: ultraviolet-visible light absorption spectrum of a reference body in a state in which the wire dispersion including a metal nanowire, an organic binder, and a solvent dissolving the organic binder is applied onto the transparent insulating substrate, and the solvent is volatilized and removed; and

third spectrum: spectrum obtained by removing the first spectrum from the second spectrum.

Here, the filtered light is advantageously band-pass filtering, and conditions of the band-pass filtering and the light irradiation conditions are similar to those described above in the manufacturing method of the nanowire transparent electrode. The above-described related contents in the manufacturing method of a nanowire transparent electrode are all included.

As described above through Relational Expression 3, the characteristics in which electrical properties are hardly deteriorated even under the ultimate in-folding test conditions of 1 mm corresponding to the radius when the paper is folded, the electrical properties are very uniform even in the ultra large area, and the sheet resistance is remarkably low are obtained when the metal nanowires applied onto the transparent insulating substrate are not twisted or warped in the light sintering process or the short axis diameter is not partially changed, and stable melting bonding is achieved at the contact points of the metal nanowire while maintaining the state where the as-fabricated metal nanowires are applied as it is.

The characteristics of the nanowire transparent electrode according to an embodiment of the present invention in which the state where the as-fabricated metal nanowires are applied is maintained as it is and the light sintering is performed may be defined by the parameters of Relational Expressions 4 and 5 below:

0.95≤H_{TCF}/H_{REF}≤1.05 (Relational Expression 4)

in Relational Expression 4, H_{T}C_{F} is a haze (%) of the nanowire transparent electrode, and H_{REF} is a haze (%) of the reference body before the wire dispersion is applied onto the transparent insulating substrate and light sintering is performed.

0.95≤T_{TCF}/T_{REF}≤1.05 (Relational Expression 5)

in Relational Expression 5, T_{TCF} is a light transmittance (%) of the nanowire transparent electrode, and T_{REF} is a light transmittance (%) of the reference body before the wire dispersion is applied onto the transparent insulating substrate and light sintering is performed.

The reference bodies in the Relational Expressions 4 and 5 may mean a state in which the wire dispersion including the metal nanowire, the organic binder, and the solvent that dissolves the organic binder is applied onto the transparent insulating substrate, i.e., a state immediately before the light sintering.

The Relational Expressions 4 and 5 mean that the haze (%) and the light transmittance (%) before and after the light sintering are substantially the same, which indicates that in the light sintering process, the metal nanowires are not twisted or warped, or the short axis diameter is not partially changed, and the light sintering is performed while the state where the as-fabricated metal nanowires are applied is maintained as it is.

The metal nanowire network may include a crossing region where two or more metal nanowires cross each other, and a height of the crossing region may satisfy Relational Expression 6 below: Here, the crossing region may be in a state in which two or more metal nanowires forming the crossing region may be melting bonded. In other words, the crossing region may be a region where two or more metal nanowires cross each other and melting bonded.

0.5≤hc/(d1+d2)≤0.7 (Relational Expression 6)

in Relational Expression 6, d1 denotes a height of one metal nanowire of two or more metal nanowires forming the crossing region based on a surface of the transparent insulating substrate, d2 denotes a height of the other metal nanowire of two or more metal nanowires forming the same crossing region based on the surface of the transparent insulating substrate, and hc denotes a height of the crossing region based on the surface of the transparent insulating substrate.

Here, d1 and d2 each may be a height of the metal nanowire (the short axis diameter, the thickness of the nanowire) based on a surface of the transparent insulating substrate at a point not in contact with the other metal nanowire by at least 100 nm or more in a length direction of the corresponding metal nanowire, and may be a height measured experimentally by scanning electron microscope. It is a well-known technique to measure the height (thickness) of a surface structure such as a nanowire by rotating or tilting an observation sample in scanning electron microscope, observing the sample, and considering these angles.

The Relational Expression 6 is a parameter indicating the degree of melting bonding in the crossing region. When hc/(d1+d2) is less than 0.5 in the Relational Expression 6, excessive melting may cause damage (deformation such as thinning, twisting, or the like) to the metal nanowires extending the crossing region, and when it is more than 0.7, there is a risk that the sheet resistance will increase due to incomplete melting bonding. More characteristically, in the nanowire transparent electrode according to an embodiment of the present invention, the metal nanowire network may satisfy hc/(d1+d2) of 0.5 to 0.6.

In the nanowire transparent electrode according to an embodiment of the present invention, the metal nanowire network may include a crossing region where two or more metal nanowires cross each other, and the metal nanowire disposed at an upper part in the crossing region may satisfy Relational Expression 7 below. Here, the metal nanowire network may satisfy Relational Expression 7 together with or independently of Relational Expression 6:

0.6do≤dnc≤1do (Relational Expression 7)

in Relational Expression 7, do denotes, in a metal nanowire disposed at the upper part in the crossing region, a height of the metal nanowire based on a surface of the transparent insulating substrate at a point not in contact with the other metal nanowire by at least 100 nm or more in a length direction of the nanowire, and dnc denotes, in the same metal nanowire disposed at the upper part in the crossing region, a height of the metal nanowire based on the surface of the transparent insulating substrate in a region within 50 nm extending in the length direction of the metal nanowire at an edge of the crossing region. Here, do and dnc each may be the height of the metal nanowire (the short axis diameter and thickness of the nanowire) based on the surface of the transparent insulating substrate, and may be the height measured by observation of the scanning electron microscope. In addition, the edge of the crossing region may mean a boundary between a point where at an upper part or a lower part of the metal nanowire in a length direction of the metal nanowire (one metal nanowire of two or more metal nanowires forming the crossing region) in the crossing region, the other metal nanowire is disposed and a point where the other metal nanowire is not disposed.

Relational Expression 7 is a characteristic condition in which electrical property is hardly deteriorated even under an ultimate in-folding test condition of 1 mm and low sheet resistance is obtained as described above in Relational Expression 3. When dnc is less than 0.6do as in the Relational Expression 7, the height (thickness) of the metal nanowires in the region near the contact point becomes remarkably small, and thus the region near the contact point during repetitive deformation may be preferentially destroyed (cut by fatigue). In addition, as shown by Relational Expression 7, when dnc is less than 0.6do, the current moving path suddenly narrows in the region near the contact point, and thus the resistance may increase. More characteristically, in the nanowire transparent electrode according to an embodiment of the present invention, the metal nanowire network may have a dnc of 0.7do to 1do, more specifically dnc of 0.8do to 1do, further more characteristically dnc of 0.85do to 1do, and still more characteristically dnc of 0.9do to 1do.

The characteristic in which very low surface resistance is obtained as in Relational Expression 1 and simultaneously the Relational Expression 7 is satisfied is capable of being implemented by the characteristic in view of the manufacturing method described above in which the filtered light is irradiated with a significantly low fluence as described above.

The present invention includes an antistatic material, an electromagnetic wave shielding material, an electromagnetic wave absorbing material, a solar cell, a fuel cell, an electric and electronic device, an electrochemical device, a secondary battery, a memory device, a semiconductor device, a photoelectric device, a notebook (notebook component), computer (computer component), personal assistant (personal assistant component), PDA (PDA component), PSP (PSP component), game machine (game machine component), display device (including field emission display (FED); back light unit (BLU); liquid crystal display (LCD); plasma display panel (PDP), a light emitting device, a medical device, a building material, a wallpaper, a light source component, a touch panel, display board, billboard, optical instrument, munitions, or the like, including the above-described nanowire transparent electrode or the nanowire transparent electrode manufactured by the above-described manufacturing method. In particular, the present invention includes a flat liquid crystal display, a touch panel, an electroluminescent device, or a photovoltaic cell, including the above-described nanowire transparent electrode or the nanowire transparent electrode manufactured by the above-described manufacturing method.

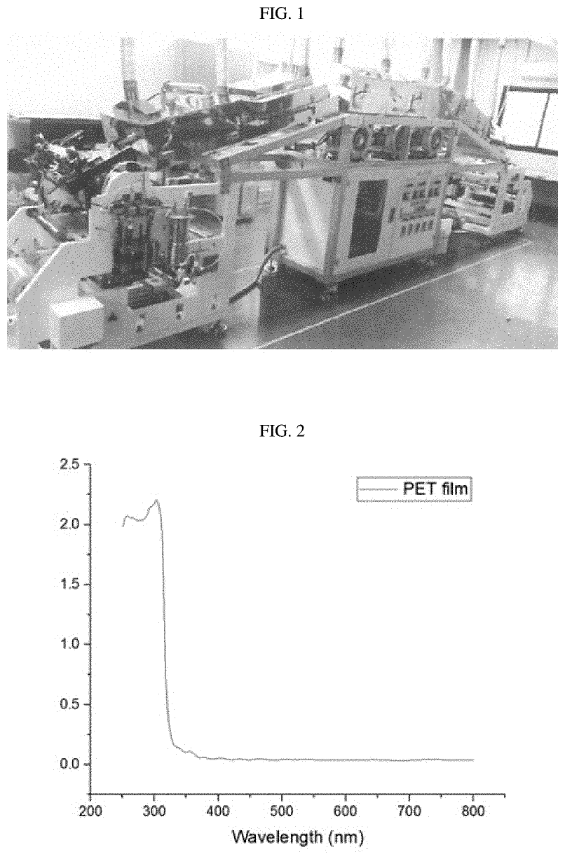

FIG. 1 is an optical image showing a process of manufacturing a nanowire transparent electrode by the manufacturing method according to the present invention using a roll-to-roll process.

Specifically, polyethylene terephthalate (PET, refractive index: 1.55) film (width of 10 cm) was used as a transparent insulating substrate, and a wire dispersion containing 0.142 wt % of a silver nanowire (average diameter of 35 nm, average length of 25 μm, absorption peak center wavelength of 415 nm), 0.138 wt % of a low molecular weight hydroxypropylmethyl cellulose (HPMC) having a weight average molecular weight of 2×10⁵ (g/mol) or less and a residual amount of water, was used. The wire dispersion was applied onto the substrate using a slot die. A line speed of the roll-to-roll process was 40 mm/sec, a slot die coating thickness was 50 μm, a discharge amount was 0.25 ml/s, a die gap was 80 μm, and a die shim was 100 μm.

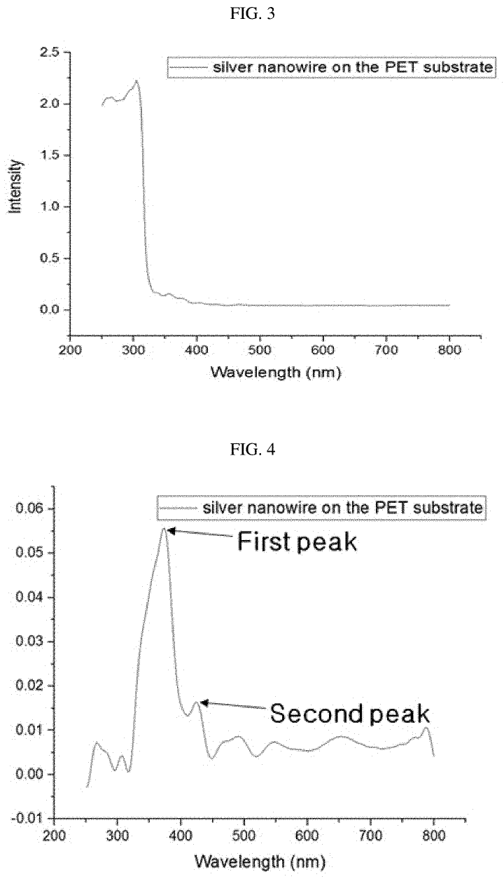

FIG. 2 shows a UV-Vis absorption spectrum (first spectrum) of the PET film itself which is the transparent insulating substrate, FIG. 3 shows a UV-Vis absorption spectrum (second spectrum) of the reference body in a state in which the wire dispersion is applied onto the PET film through the slot die and the solvent is volatilized and removed (a state before light sintering), and FIG. 4 shows a third spectrum obtained by removing the spectrum of FIG. 2 from the absorption spectrum of FIG. 3.

As appreciated from FIG. 4, the center wavelength of the relatively strongest peak was about 373 nm, and the center wavelength of the relatively second strongest peak was about 420 nm. Based on this, a Xenon lamp (350 to 950 nm wavelength) was used as a white light source and a band-pass filter that passes 400 to 500 nm wavelength (400 to 500 nm) was used, thereby performing the filtering. An optical system including a light source and a filter was constructed so that the filtered light was subjected to sheet irradiation. In the roll-to-roll process described above, application of the wire dispersion through the slot die was determined as a first stage and light irradiation by irradiating the filtered light under conditions of the fluence of 8 J/cm² and the single pulse of 10 msec was determined as a second stage, and thus the nanowire transparent electrode was continuously manufactured.

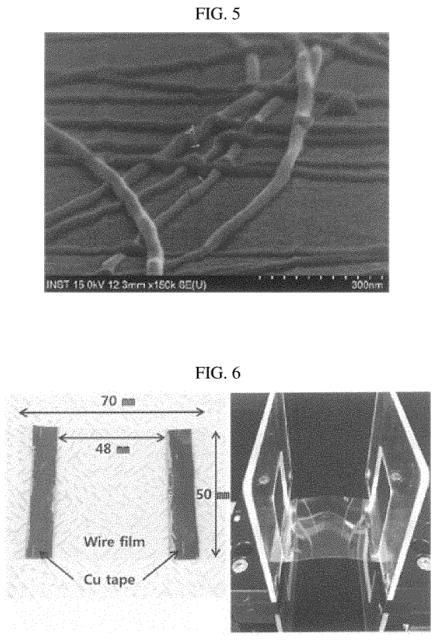

FIG. 5 is a scanning electron microscope (SEM) image of the manufactured nanowire transparent electrode. It could be appreciated from FIG. 5 that the crossing region where the nanowires cross each other were stably melting bonded, and based on the PET film surface, the height of the crossing region was 40.2 nm, and two nanowires forming the crossing region had a height of 36.2 nm and 34.5 nm, respectively, and thus hc/(d1+d2) was 0.56. Further, it could be appreciated that the height of the silver nanowires in the region within 50 nm from the edge of the crossing region was substantially the same as the height at the point where it is not in contact with the other metal nanowire by at least 100 nm or more in the length direction of the nanowire. Further, it could be appreciated from FIG. 5 that substantially all of the nanowires, including the edges of the crossing regions, were disposed in contact with the film surface by the light sintering. It could be appreciated that the nanowire regions floating in the air by crossing were melting bonded at the time of the light sintering and fell down(sink) onto the PET film.

It was confirmed that as a result obtained by measuring each surface resistance in 500 divided regions defined by evenly dividing the entire region of the nanowire transparent electrode having a width of 10 cm and a length of 2 m into an area of 2 cm×2 cm and averaging the surface resistance, the average sheet resistance of the nanowire transparent electrode was 35.2 Ω/sq., and all of the sheet resistance measured in the divided region was included in the range of 34.5 to 36.1 Ω/sq. The manufactured nanowire transparent electrode had a light transmittance of 90.33% and a haze of 1.30(%). As in the case of the sheet resistance, it was confirmed that as a result obtained by measuring the light transmittance and the haze of each of the divided regions defined by evenly dividing the entire region into an area of 2 cm×2 cm, all the light transmittance of the divided regions were included in 90.31 to 90.37%, and all the haze of the divided regions were included in 1.27 to 1.32%. As a result obtained by measuring the average sheet resistance, the transmittance, and the haze of the state before the light sintering (reference body) under the same condition as in FIG. 5, the average sheet resistance of the reference body was 60 Ω/sq., the transmittance thereof was 90.34(%), and the haze thereof was 1.29(%).

FIG. 6 is an optical image showing an in-folding test performed by cutting the manufactured nanowire transparent electrode cut into a size of 50 mm×50 mm and attaching copper tapes to both edges thereof. As a result of performing the in-folding test 500,000 times with a curvature radius of 1 mm, it was confirmed that the resistance increase rate defined by Relational Expression 3 was only 1.4%.

The sample was manufactured in the same manner as in the sample of FIG. 5, except that the white light generated from the xenon lamp was filtered by a low pass filter which is cut off at 500 nm instead of the band-pass filter, and the light filtered by the low pass filtering was irradiated under conditions of the fluence of 8 J/cm² and the single pulse of 10 msec, thereby performing the light sintering. It was confirmed that the average sheet resistance of the film obtained by the light sintering was 58 Ω/sq., and significant light sintering itself was not achieved. It was confirmed that when the fluence was increased and the low pass filtered light that was cut off at 500 nm was subjected to light sintering under the conditions of the fluence of 28 J/cm² and the single pulse of 10 msec, the average sheet resistance of the film obtained by the light sintering was about 46 Ω/sq., the light sintering was performed to some extent. However, it was confirmed that the surface resistance of each of the 500 divided regions defined by evenly dividing the entire region into an area of 2 cm×2 cm had a range of 39.1 to 57.3 Ω/sq., the uniformity of sheet resistance was also significantly lowered together with the incomplete sintering.

The sample was manufactured in the same manner as in the sample of FIG. 5, except that the white light generated from the xenon lamp was filtered by a high pass filter which is cut off at 430 nm instead of the band-pass filter, and the light filtered by the high pass filtering was irradiated under conditions of the fluence of 8 J/cm² and the single pulse of 10 msec, thereby performing the light sintering. It was confirmed that the average sheet resistance of the film obtained by the light sintering was increased as compared to the result of the low pass filter which is cut off at 500 nm, the sheet resistance similar to that of the reference body was obtained, and the light sintering was not substantially generated.

The sample was manufactured in the same manner as in the sample of FIG. 5, except that the white light generated from the xenon lamp was filtered by a low pass filter which is cut off by 400 nm instead of the band-pass filter, and the light filtered by the low-pass filtering was irradiated under conditions of the fluence of 8 J/cm² and the single pulse of 10 msec, thereby performing the light sintering. It was confirmed that the average sheet resistance of the film obtained by the light sintering was increased as compared to the result of the low pass filter which is cut off at 500 nm, and the sheet resistance similar to that of the reference body was obtained.

Further, the sample was manufactured in the same manner as in the sample of FIG. 5, except that the band-pass filtered light was irradiated with the fluence of 6 J/cm² or 10 J/cm² instead of the fluence of 8 J/cm². As a result, it was confirmed that the average surface resistance slightly increased as compared to the sample of FIG. 5, but the nanowire transparent electrode having electrical, optical and mechanical (in-folding test) properties and uniformity that are nearly similar to those of the sample of FIG. 5 was manufactured. However, it was confirmed that at the time of the light irradiation with the fluence of less than 6 J/cm², sufficient melting bonding was not achieved, and thus the sheet resistance increased sharply (about 53.2 Ω/sq.), and when irradiating band-pass filtered light with a fluence of 12 J/cm², the damage of the transparent substrate and the damage of the metal nanowires were increased, particularly, the thickness (height) of the metal nanowires adjacent to the crossing region was remarkably reduced, and in particular, the resistance increase in the in-folding test with the curvature radius of 1 mm already reached 17% at 100,000 times, and the nanowire transparent electrode was susceptible to repeated physical deformation.

Hereinabove, although the present invention is described by specific matters, limited exemplary embodiments, and drawings, they are provided only for assisting in the entire understanding of the present invention. Therefore, the present invention is not limited to the exemplary embodiments. Various modifications and changes may be made by those skilled in the art to which the present invention pertains from this description.

Therefore, the spirit of the present invention should not be limited to the above-described exemplary embodiments, and the following claims as well as all modified equally or equivalently to the claims are intended to fall within the scopes and spirit of the invention.

1. A nanowire transparent electrode comprising:
a transparent insulating substrate; and
a metal nanowire network;
wherein the nanowire transparent electrode satisfies Relational Expression 1 and Relational Expression 2:
Rₘ≤55 Ω/sq. wherein (Relational Expression 1)
in Relational Expression 1, Rₘ is an average sheet resistance of a nanowire transparent electrode having a width of 10 cm and a length of 2 m;
0.5Rₘ≤R_{loc}(i)≤1.5Rₘ, wherein (Relational Expression 2)
in Relational Expression 2, R_{loc} denotes a sheet resistance in one divided region out of 500 divided regions defined by evenly dividing the entire region of the nanowire transparent electrode having a width of 10 cm and a length of 2 m into an area of 2 cm×2 cm, and R_{loc}(i) denotes a sheet resistance of a divided region corresponding to i in sequentially numbered 500 divided regions, wherein i is a natural number of 1 to 500.

2. The nanowire transparent electrode of claim 1, wherein the nanowire transparent electrode further satisfies Relational Expression 3:
(R₅₀₀₀₀₀−R₀)/R₀×100≤3.0(%), wherein (Relational Expression 3)
in Relational Expression 3, R₀ is an average sheet resistance of the nanowire transparent electrode, and R₅₀₀₀₀₀ is an average sheet resistance after performing an in-folding test 500,000 times on the nanowire transparent electrode having a size of 5 cm×5 cm with a curvature radius of 1 mm.

3. The nanowire transparent electrode of claim 1, wherein the nanowire transparent electrode has a light transmittance of 90% or more and a haze of no more than 1.5%.

4. The nanowire transparent electrode of claim 1, wherein the metal nanowire network is obtained by:
applying a wire dispersion including a metal nanowire, an organic binder, and a solvent dissolving the organic binder onto the transparent insulating substrate;
filtering a white light to remove light corresponding to a central wavelength of a first peak, wherein the first peak is an absorption peak having a highest intensity relatively among absorption peaks of a third spectrum; and
irradiating the filtered light;
wherein the third spectrum is obtained by removing a first spectrum from a second spectrum, wherein the first spectrum comprises ultraviolet-visible light absorption spectrum of the transparent insulating substrate and the second spectrum comprises ultraviolet-visible light absorption spectrum of a reference body in a state in which the wire dispersion including the metal nanowire, the organic binder, and the solvent dissolving the organic binder is applied onto the transparent insulating substrate, and then the solvent is volatilized and removed.

5. The nanowire transparent electrode of claim 4, wherein the nanowire transparent electrode further satisfies Relational Expressions 4 and 5:
0.95≤H_{TCF}/H_{REF}≤1.05, wherein (Relational Expression 4)
in Relational Expression 4, H_{TCF} is a haze (%) of the nanowire transparent electrode, and H_{REF} is a haze (%) of a reference body before the wire dispersion is applied onto the transparent insulating substrate and light sintering is performed;
0.95≤T_{TCF}/T_{REF}≤1.05, wherein (Relational Expression 5)
in Relational Expression 5, T_{TCF} is a light transmittance (%) of the nanowire transparent electrode, and T_{REF} is a light transmittance (%) of the reference body before the wire dispersion is applied onto the transparent insulating substrate and light sintering is performed.

6. The nanowire transparent electrode of claim 1, wherein the metal nanowire network includes a crossing region where two or more metal nanowires cross each other, and a height of the crossing region satisfies Relational Expression 6:
0.5≤hc/(d1+d2)≤0.7, wherein (Relational Expression 6)
in Relational Expression 6, d1 denotes a height of one metal nanowire of the two or more metal nanowires forming the crossing region based on a surface of the transparent insulating substrate, d2 denotes a height of the other metal nanowire of the two or more metal nanowires forming the same crossing region based on the surface of the transparent insulating substrate, and hc denotes a height of the crossing region based on the surface of the transparent insulating substrate.

7. The nanowire transparent electrode of claim 1, wherein the metal nanowire network includes a crossing region where two or more metal nanowires cross each other, and a metal nanowire disposed at an upper part in the crossing region satisfies Relational Expression 7:
0.6do≤dnc≤1do, wherein (Relational Expression 7)
in Relational Expression 7, do denotes, in the metal nanowire disposed at the upper part in the crossing region, a height of the metal nanowire based on a surface of the transparent insulating substrate at a point not in contact with an other metal nanowire by at least 100 nm or more in a length direction of the nanowire, and dnc denotes, in the same metal nanowire disposed at the upper part in the crossing region, a height of the metal nanowire based on the surface of the transparent insulating substrate in a region within 50 nm extending in the length direction of the metal nanowire at an edge of the crossing region.

8. A manufacturing method fora nanowire transparent electrode comprising,
applying a wire dispersion comprising a metal nanowire, an organic binder, and a solvent that dissolves the organic binder to a transparent insulating substrate;
volatilizing the solvent; and
light sintering the transparent insulating substrate with the wire dispersion by irradiating with filtered light, wherein the filtered light is a third spectrum obtained by removing a first spectrum from a second spectrum;
wherein the first spectrum is an ultraviolet-visible light absorption spectrum of a transparent insulating substrate; and
wherein the second spectrum is an ultraviolet-visible light absorption spectrum of a reference body in a state in which the wire dispersion including a metal nanowire generates surface plasmon.

9. The manufacturing method of claim 8, wherein the filtering passes light corresponding to a central wavelength of a second peak, wherein the second peak is an absorption peak having a second highest intensity relatively among light absorption peaks of the third spectrum.

10. The manufacturing method of claim 9, wherein the removes light having a wavelength more than 1.3 times the central wavelength of the second peak at the time of the filtering.

11. The manufacturing method of claim 9, wherein the filtering is band-pass filtering, and a minimum wavelength of the filtered light is disposed between a center wavelength of a first peak and the center wavelength of the second peak, wherein the first peak is an absorption peak having a highest intensity relatively among light absorption peaks of the third spectrum.

12. The manufacturing method of claim 11, wherein a bandwidth which is a difference between a maximum wavelength and a minimum wavelength of the filtered light is 150 nm or less.

13. The manufacturing method of claim 11, wherein a pass band of the band-pass filtering has a minimum wavelength of 380 to 410 nm and a maximum wavelength of 430 to 550 nm.

14. The manufacturing method of claim 8, wherein at a time of the light sintering using the filtered light, the filtered light has a fluence of 6 to 10 J/cm².

15. The manufacturing method of claim 8, wherein applying the wire dispersion and the light sintering are continuous processes.

16. The manufacturing method of claim 8, wherein the manufacturing method further comprises:
unwinding the transparent insulating substrate wound in a roll form;
applying the wire dispersion to the unwound transparent insulating substrate;
and
washing the light-irradiated transparent insulating substrate and rewinding the transparent insulating substrate again in a roll form.

17. A nanowire transparent electrode manufactured by the manufacturing method of claim 8.
